(19) United States
(12) Patent Application Publication
(10) Pub. No.: US 2016/0093801 A1
(43) Pub. Date: Mar. 31, 2016

(54) MEMORY DEVICE AND METHOD OF MANUFACTURING THE SAME

(71) Applicant: Kabushiki Kaisha Toshiba, Minato-ku (JP)

(72) Inventor: Kiyohito NISHIHARA, Yokkaichi (JP)

(73) Assignee: Kabushiki Kaisha Toshiba, Minato-ku (JP)

(21) Appl. No.: 14/637,622

(22) Filed: Mar. 4, 2015

(30) Foreign Application Priority Data
Sep. 30, 2014 (JP) 2014-202640

(51) Int. Cl. H01L 45/00; H01L 27/24

(52) U.S. Cl. CPC H01L 45/085; H01L 45/1233; H01L 45/1253; H01L 45/146; H01L 45/144; H01L 45/148; H01L 45/1608; H01L 27/2463

(57) ABSTRACT

According to one embodiment, a memory device includes a substrate, a first wiring layer including a first interconnect extending in a first direction which is disposed on the substrate, a second wiring layer including a second interconnect which is disposed so as to extend in a second direction intersecting the first direction above the first wiring layer, a memory cell which is disposed between the first interconnect and the second interconnect, and a pattern which is spaced from the memory cell. The memory cell and the pattern, respectively, includes a resistance change layer which is disposed between the first wiring layer and the second wiring layer, and an electrode layer which is provided below the second wiring layer and directly above the resistance change layer, and the memory cell further including a metal source layer which is provided between the resistance change layer and the electrode layer.

### CROSS-REFERENCE TO RELATED APPLICATIONS

This application is based upon and claims the benefit of priority from Japanese Patent Application No. 2014-202640, filed on Sep. 30, 2014; the entire contents of which are incorporated herein by reference.

### FIELD

Embodiments described herein relate generally to a memory device and a method for manufacturing the same.

### BACKGROUND

In recent years, there has been progress in the high integration of a semiconductor memory device. As one method of high integration, a three-dimensional memory device has been developed. In this three-dimensional memory device, there is a problem in that it is difficult to suppress an increase in leakage current.

### BRIEF DESCRIPTION OF THE DRAWINGS

FIG. 1 is a schematic configuration diagram of a memory device according to a first embodiment;

FIG. 2 is a perspective illustration showing a schematic configuration of the memory cell array of the memory device according to the first embodiment;

FIG. 3 is a schematic configuration of a memory cell according to a first embodiment;

FIG. 4 is a schematic plan view showing a memory cell region Rm and a conductive line lead region Rp of the memory device according to the first embodiment;

FIG. 5A to FIG. 5C are cross-sectional views showing the memory device according to the first embodiment;

FIG. 6A to FIG. 6C are cross-sectional views showing a manufacturing process according to the first embodiment (part 1);

FIG. 7A to FIG. 7C are cross-sectional views showing a manufacturing process according to the first embodiment (part 2);

FIG. 8A to FIG. 8C are cross-sectional views showing a manufacturing process according to the first embodiment (part 3);

FIG. 9A to FIG. 9C are cross-sectional views showing a manufacturing process according to the first embodiment (part 4);

FIG. 10A to FIG. 10C are cross-sectional views showing a manufacturing process according to the first embodiment (part 5);

FIG. 11A to FIG. 11C are cross-sectional views showing a manufacturing process according to the first embodiment (part 6);

FIG. 12A to FIG. 12C are cross-sectional views showing a manufacturing process according to the first embodiment (part 7);

FIG. 13A to FIG. 13C are cross-sectional views showing a manufacturing process according to the first embodiment (part 8);

FIG. 14A to FIG. 14C are cross-sectional views showing a manufacturing process according to the first embodiment (part 9);

FIG. 15A to FIG. 15C are cross-sectional views showing a manufacturing process according to the first embodiment (part 10);

FIG. 16 is a schematic plan view showing a memory cell region Rm and a conductive line lead region Rp of the memory device according to the first embodiment;

FIG. 17A to FIG. 17C are cross-sectional views showing the memory device according to the first embodiment;

FIG. 18A to FIG. 18C are cross-sectional views showing a manufacturing process according to the second embodiment (part 1);

FIG. 19A to FIG. 19C are cross-sectional views showing a manufacturing process according to the second embodiment (part 2);

FIG. 20A to FIG. 20C are cross-sectional views showing a manufacturing process according to the second embodiment (part 3);

FIG. 21A to FIG. 21C are cross-sectional views showing a manufacturing process according to the third embodiment (part 1);

FIG. 22A to FIG. 22C are cross-sectional views showing a manufacturing process according to the third embodiment (part 2);

FIG. 23A to FIG. 23C are cross-sectional views showing a manufacturing process according to the third embodiment (part 3);

FIG. 24A to FIG. 24C are is a cross-sectional views showing a manufacturing process according to the third embodiment (part 4);

FIG. 25A to FIG. 25C are cross-sectional views showing a manufacturing process according to the fourth embodiment (part 1);

FIG. 26A to FIG. 26C are cross-sectional views showing a manufacturing process according to the fourth embodiment (part 2); and

FIG. 27A to FIG. 27C are cross-sectional views showing a manufacturing process according to the fourth embodiment (part 3).

### DETAILED DESCRIPTION

In general, according to one embodiment, a memory device includes a substrate, a first wiring layer including a first interconnect extending in a first direction which is disposed on the substrate, a second wiring layer including a second interconnect which is disposed so as to extend in a second direction intersecting the first direction above the first wiring layer, a memory cell which is disposed between the first interconnect and the second interconnect, and a pattern which is spaced from the memory cell. The memory cell and the pattern, respectively, includes a resistance change layer which is disposed between the first wiring layer and the second wiring layer, and an electrode layer which is provided below the second wiring layer and directly above the resistance change layer, and the memory cell further including a metal source layer which is provided between the resistance change layer and the electrode layer.

Hereinafter, embodiments of the invention will be described with reference to the accompanying drawings.

Meanwhile, in the following description, the side close to the substrate side is represented as a lower side, for the sake of convenience.

### First Embodiment

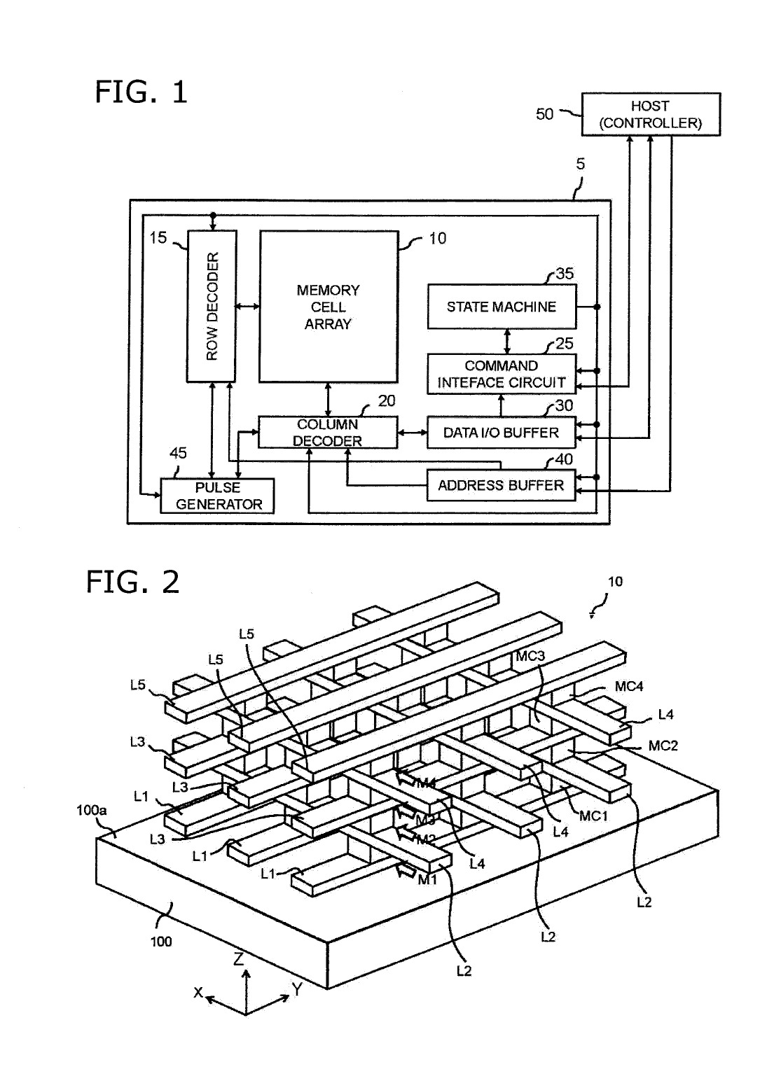

FIG. 1 is a block diagram illustrating a configuration of a memory device 5 according to a first embodiment.

As shown in FIG. 1, the memory device 5 includes a memory cell array 10, a row decoder 15, a column decoder 20, a command interface circuit 25, a data input and output buffer 30, a state machine 35, an address buffer 40, and a pulse generator 45.

The memory cell array 10 has a plurality of interconnects and a plurality of other interconnects that stereoscopically intersect the interconnects. A memory cell is formed at the stereoscopic intersecting portion between the interconnects and the other interconnects.

The row decoder 15 is disposed at one end of the memory cell array 10, and the column decoder 20 is disposed at the other end thereof.

The row decoder 15 selects the row of the memory cell array 10, for example, on the basis of a row address signal. In addition, the column decoder 20 selects the column of the memory cell array 10 on the basis of a column address signal.

The command interface circuit 25 receives a control signal from a controller 50 (for example, a memory controller or a host). In addition, the data input and output buffer 30 receives data from the state machine 35.

The command interface circuit 25 determines whether data from the controller 50 is command data on the basis of the control signal. When the data is command data, the circuit transfers the command data from the data input and output buffer 30 to the state machine 35.

The state machine 35 manages an operation of a resistance change memory on the basis of the command data. For example, the state machine 35 manages a set/reset operation and a readout operation on the basis of the command data from the controller 50. In addition, the state machine 35 also controls the row decoder 15, the column decoder 20, and the like.

The address buffer 40 receives an address signal from the controller 50 in the set/reset operation and the readout operation. The address signal includes, for example, a memory cell array selection signal, a row address signal and a column address signal. The address signal is input to the row decoder 15 and the column decoder 20 through the address buffer 40.

The pulse generator 45 outputs, for example, a voltage pulse or a current pulse required for the set/reset operation and the readout operation at a predetermined timing, on the basis of a command from the state machine 35.

The controller 50 can receive status information which is managed by the state machine 35, and also determine operation results of the resistance change memory.

Meanwhile, the controller 50 may be disposed in the memory device 5, and may be provided outside the memory device 5.

Reference will be made to FIG. 2 to describe the basic configuration of the memory cell array 10 according to the embodiment. Meanwhile, in the specification, an XYZ direct coordinate system is adopted for convenience of description. Two directions which are perpendicular to each other and parallel to an upper surface 100a of a substrate (for example, silicon substrate) 100 are referred to as an “X-direction” and a “Y-direction”, and a direction perpendicular to the upper surface 100a is referred to as a “Z-direction”.

As shown in FIG. 2, the memory cell array 10 is disposed above the substrate 100. Meanwhile, a circuit element such as a MOS transistor and an insulating film may be formed between the memory cell array 10 and the substrate 100.

FIG. 2 shows an example in which the memory cell array 10 includes four memory cell array layers M1, M2, M3, and M4 which are stacked in the Z-direction.

The memory cell array layer M1 includes a memory cell MC1 which is disposed on the array in the X-direction and the Y-direction.

Similarly, the memory cell array layer M2 includes a memory cell MC2 which is disposed on the array, the memory cell array layer M3 includes a memory cell MC3 which is disposed on the array, and the memory cell array layer M4 includes a memory cell MC4 which is disposed on the array.

In the following, when the memory cell array layers M1, M2, M3, and M4 are not distinguished from each other, the memory cell array layers are simply called a memory cell array layer M. In addition, when the memory cells MC1, MC2, MC3, and MC4 are not distinguished from each other, the memory cells are simply called a memory cell MC.

A first conductive line L1, a second conductive line L2, a third conductive line L3, a fourth conductive line L4, and a fifth conductive line L5 are disposed on the substrate 100 in order from the substrate 100. In the following, when these conductive lines are not required to be particularly distinguished from each other, the conductive lines are called the conductive line L1, the conductive line L2, the conductive line L3, the conductive line L4, and the conductive line L5, respectively, or simply the conductive line L.

The conductive lines odd-numbered from the substrate 100 side, that is, the conductive lines L1, L3, and L5 extend in the Y-direction. The conductive lines even-numbered from the substrate 100 side, that is, the conductive lines L2 and L4 extend in the X-direction.

These conductive lines function as word lines or bit lines.

The first memory cell array layer M1 is disposed between the first conductive line L1 and the second conductive line L2 located. In the set/reset operation and the readout operation for the memory cell array layer M1, one of the first conductive line L1 and the second conductive line L2 is used as a word line, and the other thereof is used as a bit line.

The same is true of the memory cell array layers M2 to M4.

That is, the memory cell array layer M2 is disposed between the second conductive line L2 and the third conductive line L3. One of the second conductive line L2 and the third conductive line L3 is used as a word line, and the other thereof is used as a bit line.

The memory cell array layer M3 disposed between the third conductive line L3 and the fourth conductive line L4. One of the third conductive line L3 and the fourth conductive line L4 is used as a word line, and the other thereof is used as a bit line.

The memory cell array layer M4 is disposed between the fourth conductive line L4 located at a fourth position and the fifth conductive line L5 located at a fifth position. One of the fourth conductive line L4 and the fifth conductive line L5 is used as a word line, and the other thereof is used as a bit line.

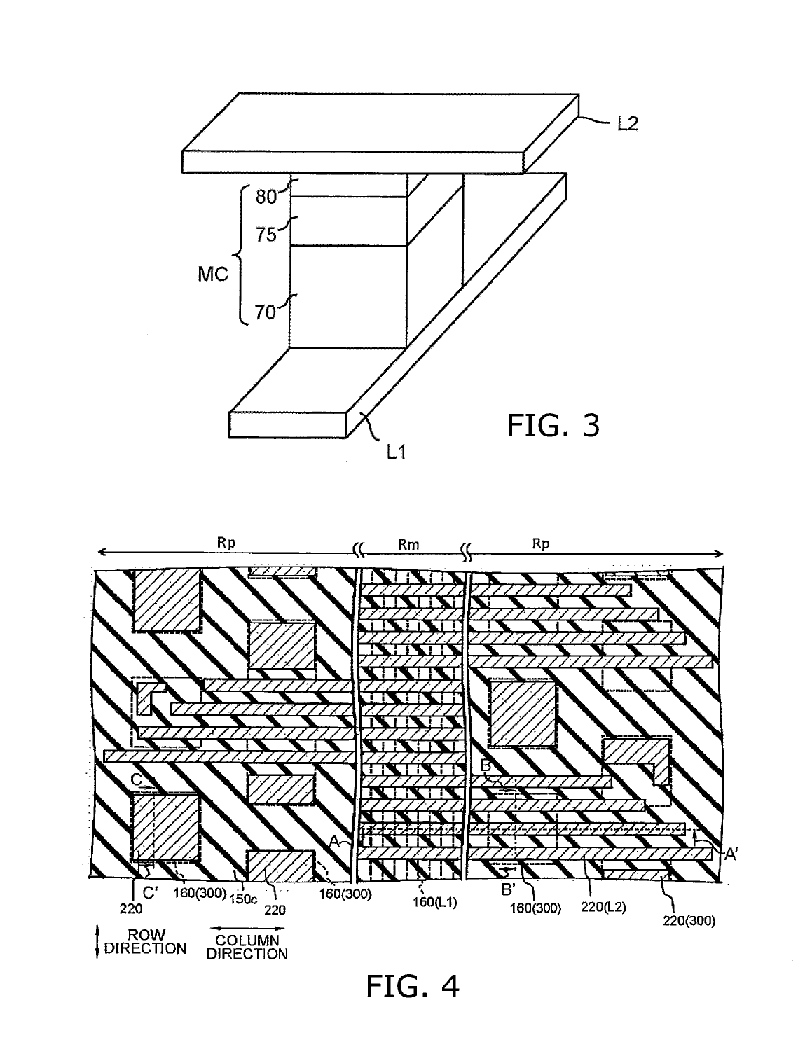

FIG. 3 is a diagram schematically illustrating a basic structure of the memory cell MC. Meanwhile, FIG. 3 illustrates the memory cell MC1 which is formed between the first conductive line L1 and the second conductive line L2, as an example of the memory cell MC, but the same is true of any memory cell MC without being naturally limited thereto.

The memory cell MC includes an element selection layer 70 provided on the first conductive line L1, a resistance change layer 75 provided thereon, and a metal source layer 80 provided thereon.

The element selection layer 70 is a layer for controlling whether a current is caused to flow to the memory cell MC, and is, for example, silicon diode. In addition, an element used in the layer is metal oxynitride, metal nitride, silicon oxide, silicon nitride, silicon oxynitride, silicon, a stacked body thereof, or the like.

The resistance change layer 75 includes for example, metal oxide such as aluminum oxide, hafnium oxide, and zirconium oxide, or silicon oxide. The resistance change layer 75 includes may include an alloy of germanium, antimony, and tellurium.

The resistance change layer 75 is configured such that when a predetermined voltage is applied, a filament is formed therein by a metal ionized from the metal source layer 80, and its electrical resistance value is reduced. That is, the resistance change layer 75 is set to be in a low resistance state. In addition, when the predetermined voltage is applied, the filament is shortened, and its electrical resistance value increases. That is, the resistance change layer 75 is set to be in a high resistance state.

For example, in the resistance change layer 75, the high resistance state is set to “1”, and the low resistance state is set to “0”, thereby allowing, for example, binary data to be stored in the memory cell MC. Naturally, the high resistance state may be set to “0”, and the low resistance state may be set to “1”.

The metal source layer 80 are made of, for example, gold, silver, palladium, iridium, platinum, tungsten, hafnium, zirconium, titanium, nickel, cobalt, aluminum, chromium, copper, or the like.

Next, the plan view of the embodiment will be described with reference to FIG. 4. Meanwhile, for convenience of description, the first conductive line (first wiring layer) L1 is set to a word line, and the extending direction (X-direction) of the first conductive line L1 is set to a row direction. Similarly, the second conductive line (second wiring layer) L2 is set to a bit line, and the extending direction (Y-direction) of the second conductive line L2 is set to a column direction. Meanwhile, naturally, the first conductive line L1 may be set to a bit line, and the second conductive line L2 may be set to a word line.

FIG. 4 is a plan view in a state where the second conductive line L2 is formed, and then an interlayer dielectric film 150c is forms between the second conductive lines L2 and is planarized using a chemical mechanical polishing (CMP) method. Meanwhile, a first conductive line material 160 located below the interlayer dielectric film 150c is shown by a broken line. Here, the first conductive line material 160 is a material for forming the first conductive line L1. Meanwhile, a material for forming the second conductive line L2 is called a second conductive line material 220.

The first conductive line L1 is provided so as to intersect the second conductive line L2. The memory cell MC is formed at an intersection location. A region in which the first conductive line L1 and the second conductive line L2 intersect each other is called a memory cell region Rm.

On the other hand, a region in which the memory cell is not formed and connection portions (not shown) of the first conductive line L1 and the second conductive line L2 to an upper-layer interconnect or a lower-layer interconnect are formed is called a conductive line lead region Rp.

Meanwhile, a method of forming a connection portion may be a general method. In addition, in the first conductive line L1 and the second conductive line L2, a pattern for the connection portion may be formed.

FIG. 4 shows an example in which every four second conductive lines L2 have the lead direction thereof changed to both sides of the memory cell region Rm.

As shown in FIG. 4, a pattern 300 is disposed in the conductive line lead region Rp. The pattern 300 indicates a region in which at least one of the first conductive line material 160 which is not connected to the memory cell MC or the second conductive line material 220 which is not connected to the memory cell MC is formed. Meanwhile, as described later, the pattern 300 may be formed on the first conductive line L1, and the pattern 300 can also be formed below the second conductive line L2.

The pattern 300 is disposed so as to be easily planarized based on CMP. The size thereof may be, for example 10 nm to several um, and may have any arrangement. The shape thereof may also have any figure without being limited to a quadrangle. The arrangement of the patterns 300 can be made arbitrarily so as to be capable of being easily planarized based on CMP with a coverage factor without causing dishing or the like.

Meanwhile, the second conductive line material 220 relating to the pattern 300 is disposed so as not to be short-circuited to the second conductive line L2. Specifically, as shown in FIG. 4, when the pattern 300 and the second conductive line L2 are formed so as to overlap each other, the second conductive line material 220 relating to the pattern 300 is provided at a predetermined distance from the second conductive line L2.

Similarly, the first conductive line material 160 relating to the pattern 300 is disposed so as not to be short-circuited to the first conductive line L1. When the pattern 300 and the first conductive line L1 are formed so as to overlap each other, the first conductive line material 160 relating to the pattern 300 is provided at a predetermined distance from the first conductive line L1.

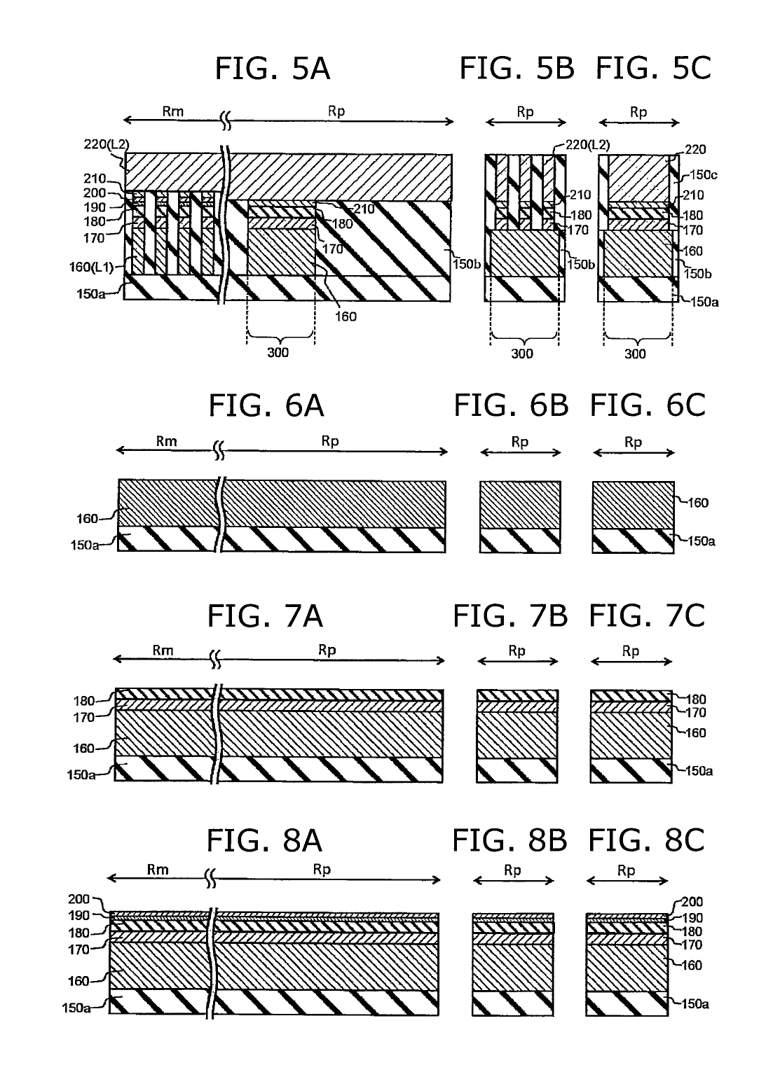

Hereinafter, the pattern 300 will be described with reference to the cross-sectional view of FIGS. 5A to 5C. FIG. 5A is a cross-sectional view taken along line A-A′ of FIG. 4. FIG. 5B is a cross-sectional view taken along line B-B′ of FIG. 4. FIG. 5C is a cross-sectional view taken along line C-C′ of FIG. 4.

FIG. 5A is a diagram when a region in which the second conductive line and the pattern 300 are formed so as to overlap each other, and the column direction cross-section of the memory cell are viewed from a row direction.

In the memory cell region Rm of FIG. 5A, the first conductive line L1, that is, the first conductive line material 160 is formed on an interlayer dielectric film 150a at a predetermined interval. A silicon layer 170 is formed above the first conductive line L1.

A silicon oxide layer 180 is formed above the silicon layer 170. A silver layer 190 is formed above the silicon oxide layer 180.

Here, the silicon layer 170 is an example of the element selection layer 70. The silicon oxide layer 180 is an example of the resistance change layer 75. The silver layer 190 is an example of the metal source layer 80.

A barrier metal layer 200 is formed above the silver layer 190. The barrier metal layer 200 suppresses, for example, the condensation of the silver layer 190, the diffusion of silver in the silver layer 190, or the change of characteristics due to the oxidation of the silver layer 190.

A CMP stopper electrode layer 210 is formed on the barrier metal layer 200. The CMP stopper electrode layer 210 facilitates planarization based on CMP. An element used in the CMP stopper electrode layer 210 is, for example, tungsten.

For example, when a silicon oxide film is removed by CMP, a change in rotational speed, a change in frictional force, a change required for rotation, or the like occurs at a point in time when the CMP stopper electrode layer 210 is exposed. It is possible to easily control planarization based on CMP by detecting these changes.

The second conductive line material 220 is formed on the CMP stopper electrode layer 210, and the second conductive line L2 is formed thereon. In addition, the CMP stopper electrode layer 210 also functions as an electrode which is electrically connected to the second conductive line L2.

The pattern 300 is formed in the conductive line lead region Rp of FIG. 5A. In the pattern 300, the first conductive line material 160, the silicon layer 170, the silicon oxide layer 180, and the CMP stopper electrode layer 210 are formed, in order, on the interlayer dielectric film 150a. The second conductive line material 220, that is, the second conductive line L2 is formed on the CMP stopper electrode layer 210.

In other words, the silver layer 190 and the barrier metal layer 200 are not formed in the pattern 300.

An interlayer dielectric film 150b is formed in a region other than the pattern 300 of the conductive line lead region Rp shown in FIG. 5A. The second conductive line material 220 is formed on the interlayer dielectric film 150b. Meanwhile, connection portions to an upper-layer interconnect and a lower-layer interconnect may be provided as necessary.

FIG. 5B is a diagram when the row direction cross-section of pattern 300 in FIG. 5A is viewed from a column direction. Therefore, an interlayer film structure is the same as that of the pattern 300 shown in FIG. 5A.

In the pattern 300 of FIG. 5B, the silicon layer 170, the silicon oxide layer 180, the CMP stopper electrode layer 210, and the second conductive line material 220 are separated from each other at a predetermined interval. The second conductive line material 220 forms the second conductive line L2. In addition, the interlayer dielectric film 150b is formed between the separated regions.

FIG. 5C is a diagram when the row direction cross-section of the first conductive line L1 and the pattern 300 formed in a region which does not overlap the second conductive line L2 is viewed from a column direction.

The film structure of the pattern 300 relating to FIG. 5C is the same as that of the pattern 300 relating to FIG. 5A and FIG. 5B. Meanwhile, in FIG. 5C, the width of the first conductive line material 160 in a row direction is shown to be larger than the width of the second conductive line material 220 in a row direction, but may be smaller than that.

Hereinafter, a manufacturing method will be described with reference to FIGS. 6 to 15. In FIGS. 6 to 15, parts A, unless otherwise stated, parts B, and parts C of the respective figures are schematic cross-sectional views taken along line A-A′, line B-B′, and line C-C′ of FIG. 4, respectively.

First, a circuit element (not shown) such as a transistor is formed on the substrate 100 (not shown). Subsequently, the interlayer dielectric film 150a is formed on the substrate 100. The interlayer dielectric film 150a is, for example, a silicon oxide film.

As shown in FIGS. 6A to 6C, the first conductive line material 160 is formed on the interlayer dielectric film 150a. The first conductive line material 160 includes, for example, a barrier metal film and a metal film. An element used in the barrier metal film is titanium, tantalum, titanium nitride, tantalum nitride or a stacked body thereof. An element used in the metal film is copper, aluminum, tungsten, or the like. In a film formation method, a film is formed using, for example, a sputtering method or a CVD (Chemical Vapor Deposition) method.

As shown in FIGS. 7A to 7C, the silicon layer 170 is formed on the first conductive line material 160. The silicon oxide layer 180 is formed on the silicon layer 170. The silicon layer 170 is made of silicon. The silicon oxide layer 180 is made of silicon oxide. As a method of forming the silicon layer 170 or the silicon oxide layer 180, for example, a CVD method is used.

As shown in FIGS. 8A to 8C, the silver layer 190 and the barrier metal layer 200 are formed, in order on the silicon oxide layer 180. An element used in the silver layer 190 is silver. An element used in the barrier metal layer 200 is, for example, titanium, tantalum, titanium nitride, tantalum nitride, or a stacked body thereof.

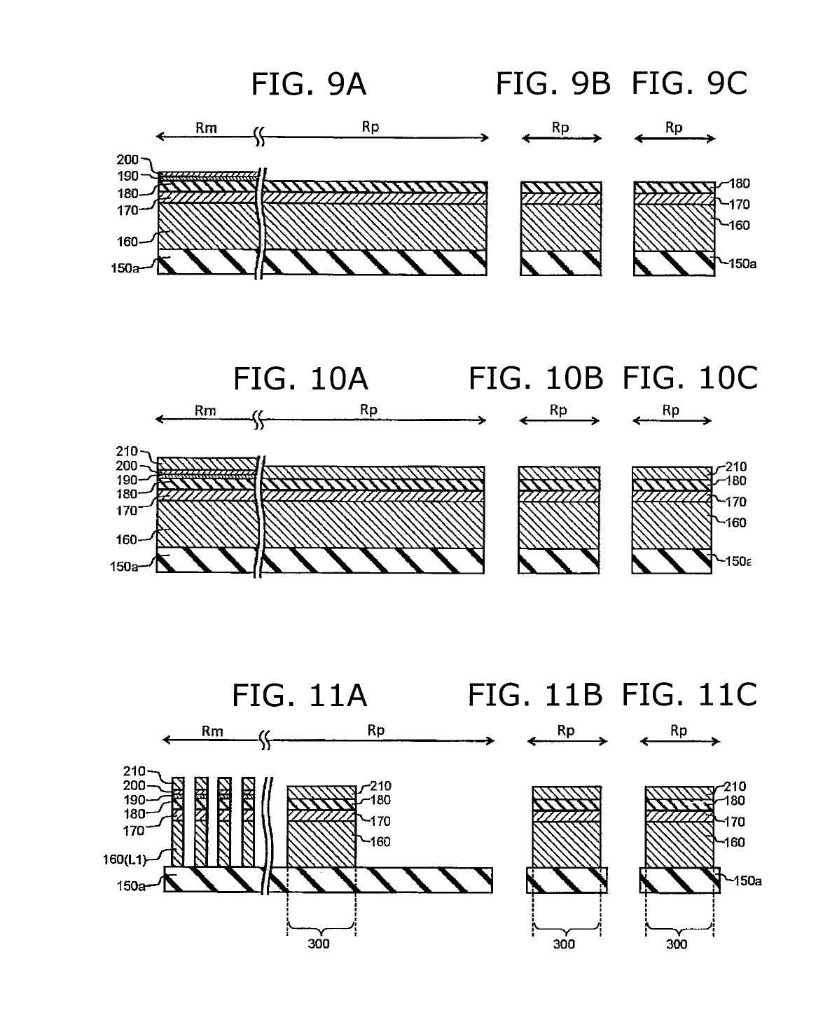

As shown in FIGS. 9A to 9C, next, the barrier metal layer 200 and the silver layer 190 in the conductive line lead region Rp are removed. A desired mask pattern is formed on the barrier metal layer 200 of the memory cell region Rm by a lithography method or the like. Using this mask pattern as a mask, the barrier metal layer 200 and the silver layer 190 are removed by an etching process using an RIE (Reactive Ion Etching) method or the like.

A stepped difference occurs in the memory cell region Rm and the conductive line lead region Rp due to the above-mentioned etching process. The barrier metal layer 200 and the silver layer 190 are, for example, 5 to 10 nm in thickness. Thus, the stepped difference is, for example, 10 to 20 nm in thickness.

Subsequently, as shown in FIGS. 10A to 10C, the CMP stopper electrode layer 210 is formed. The CMP stopper electrode layer 210 includes, for example, a barrier metal film and the metal film. The barrier metal film is, for example, made of titanium, tantalum, titanium nitride, tantalum nitride, or a stacked body thereof. The metal film is made of aluminum, copper, tungsten, or the like. Meanwhile, the barrier metal film may not be included.

As shown in FIGS. 11A to 11C, an etching process is performed. A desired mask material is formed on the CMP stopper electrode layer 210, and a desired mask pattern is formed on the mask material. Using this mask pattern as a mask, the CMP stopper electrode layer 210, the barrier metal layer 200, the silver layer 190, the silicon oxide layer 180, the silicon layer 170, and the first conductive line material 160 are etched by RIE. Thereafter, the mask pattern and the mask material are removed. The first conductive line material 160 is separated in a column direction by this etching process, and the first conductive line L1 is formed. In addition, the first conductive line material 160 relating to the pattern 300 is separated.

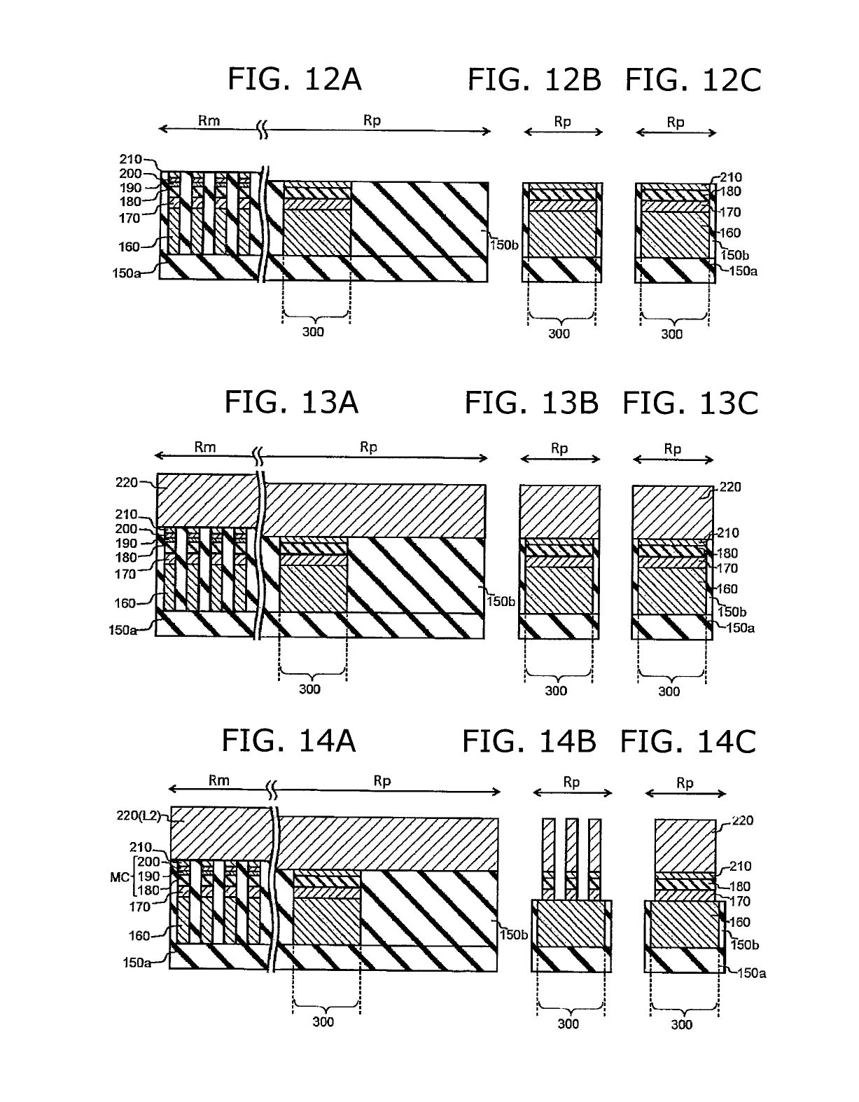

As shown in FIGS. 12A to 12C, the interlayer dielectric film 150b is formed, and planarization is performed based on CMP using the CMP stopper electrode layer 210 as a stopper. The CMP stopper electrode layer 210 and the interlayer dielectric film 150b are planarized by the planarization based on CMP. Meanwhile, silicon oxide is used, for example, in the interlayer dielectric film 150b.

Meanwhile, a stepped difference between the memory cell region Rm and the conductive line lead region Rp which are formed when the silver layer 190 and the barrier metal layer 200 are removed by etching may remain as it is. In addition, the interlayer dielectric film 150b may remain above the pattern 300.

As shown in FIGS. 13A to 13C, the second conductive line material 220 is formed on the planarized interlayer dielectric film 150b and the CMP stopper electrode layer 210. The second conductive line material 220 includes, for example, a barrier metal film and a metal film. An element used in the barrier metal film is titanium, tantalum, titanium nitride, tantalum nitride or a stacked body thereof. An element used in the metal film is copper, aluminum, tungsten, or the like. In a film formation method, a film is formed using, for example, a sputtering method or a CVD method. The film thickness of the second conductive line material is typically 50 to 150 nm.

As shown in FIGS. 14A to 14C, the second conductive line L2 is formed by etching. A desired mask material is formed on the second conductive line material 220, and a desired mask pattern is formed on the mask material. Using this mask pattern as a mask, the second conductive line material 220, the CMP stopper electrode layer 210, the barrier metal layer 200, the silver layer 190, the silicon oxide layer 180, and the silicon layer 170 are etched by RIE or the like. Thereafter, the mask pattern and the mask material are removed. The second conductive line material 220 is separated in a row direction by this etching process, and the second conductive line L2 is formed.

In addition, in the memory cell region Rm, the CMP stopper electrode layer 210, the barrier metal layer 200, the silver layer 190, the silicon oxide layer 180, and the silicon layer 170 are separated in a row direction and a column direction, and the memory cell MC is formed.

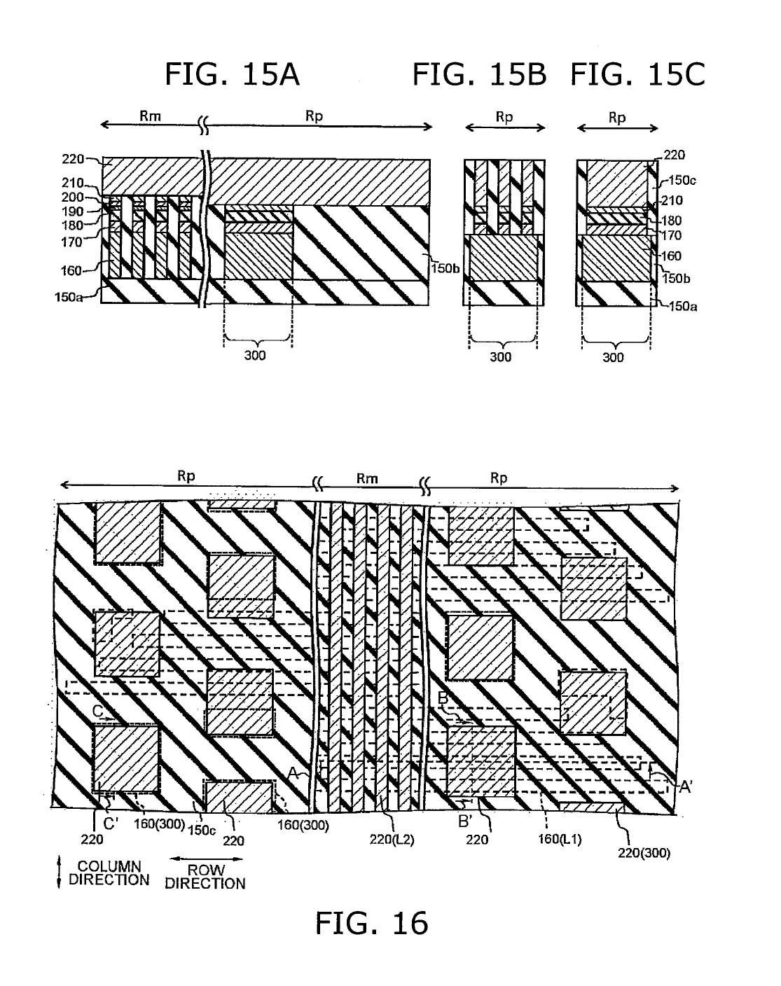

As shown in FIGS. 15A to 15C, the interlayer dielectric film 150c is formed, and the second conductive line material 220 and the interlayer dielectric film 150c are planarized by CMP. Silicon oxide is used, for example, in the interlayer dielectric film 150c.

Meanwhile, as shown in FIGS. 15A to 15C, planarization can be performed on the stepped difference between the memory cell region Rm and the conductive line lead region Rp. This is because the film thickness of the second conductive line material 220 is sufficiently larger than the stepped difference, and a planarization process based on CMP can be sufficiently performed.

According to the following method of manufacturing a standard memory device, the memory device of the embodiment is manufactured.

Next, effects of the embodiment will be described.

In FIG. 4 and FIGS. 5A to 5C, the pattern 300 is formed in a region adjacent to the conductive line lead region Rp, that is, the memory cell region Rm.

The pattern 300 is formed, thereby allowing planarization based on CMP after the formation of the interlayer dielectric film 150b in FIGS. 11A to 12C to be easily performed.

When the pattern 300 is not present, the CMP stopper electrode layer 210 resistant to the etching of a CMP process is not present in the conductive line lead region Rp throughout a wide region.

When a stopper film having etching resistance to the CMP process is not present in a wide region, over-polishing is likely to occur in the CMP process. That is, etching based on the CMP process is performed excessively in a region having no stopper film, and thus there is the possibility of planarization not being able to be performed sufficiently.

Consequently, as in the embodiment, the pattern 300 is disposed in the conductive line lead region Rp, thereby allowing planarization based on CMP to be performed easily.

In addition, in order to facilitate the CMP using the above-mentioned pattern 300, it is preferable that the pattern 300 is disposed at a predetermined interval. In order to prevent over-polishing of the above-mentioned CMP process, and to easily manufacture a memory device, it is preferable to be able to dispose the pattern 300 regardless of the presence or absence of the first conductive line L1 and the second conductive line L2.

However, when the pattern 300 is formed in a region in which the pattern 300 and the second conductive line L2 overlap each other so as to have the same film structure as that of the memory cell MC, a problem occurs in that a leakage current has a tendency to be generated between the second conductive lines L2.

That is, when the silver layer 190 is present in the pattern 300, a leakage current has a tendency to be generated between the second conductive lines L2, which leads to malfunction of the memory device.

The above-mentioned leakage current is generated by some causes. Hereinafter, three causes will be described.

A first cause of the leakage current includes the attachment of by-products during the etching process of the second conductive line L2 described in FIG. 14B. That is, when the etching process is performed on the silver layer, conductive by-products are attached to the sidewalls of the silicon layer 170 and the silicon oxide layer 180 which are located above the pattern 300.

When the conductive by-products are attached, a current flows from the second conductive line L2 located above the pattern 300 through the by-products to the first conductive line material 160, and a leakage current flows to another second conductive line L2 through the by-products.

In addition, a second cause of the leakage current will be described.

Originally, silver in the silver layer is diffused to the silicon oxide layer to form a filament, and thus the resistance value of the silicon oxide layer is changed. That is, the silver in the silver layer has a tendency to be diffused by the application of a voltage.

Here, the voltage which is applied to the memory cell MC is operated so as to be controlled using a voltage by which the silver in the silver layer is not abnormally diffused in order to operate the memory device. However, it is normal to determine a voltage operation without considering whether the silver in the silver layer relating to the pattern 300 is diffused.

Further, a voltage is applied to the second conductive line L2 even during access to which memory cell MC that is connected to the second conductive line L2. That is, there is the possibility of the number of times of voltage application being larger than that in the memory cell MC. There is the possibility of the silver being diffused to a greater degree than in the memory cell MC due to the larger number of times of voltage application.

Thus, the silver in the silver layer relating to the pattern 300 is diffused to the silicon oxide layer 180 and the silicon layer 170 relating to the pattern 300 due to the voltage application or the like, and thus electrical resistance is lowered. Then, a leakage current flows from the second conductive line L2 on the pattern 300 through the silicon oxide layer 180, the silicon layer 170, and the first conductive line material 160 relating to the pattern 300 to another second conductive line L2.

Further, a third cause of the leakage current will be described. A heat load is applied in a process of manufacturing a memory device. The silver in the silver layer is diffused due to the heat load. That is, the silver is diffused by the heat load of a manufacturing process regardless of the above-mentioned voltage application. Here, when the silver layer is also present in the pattern 300 in addition to the memory cell MC, an area in which the silver layer is present increases. That is, the diffusion of the silver due to the heat load increases, and thus there is the possibility of the leakage current increasing.

According to the manufacturing method of the embodiment, the silver layer 190 is removed before the etching process of the first conductive line L1 and the second conductive line L2, in the etching process described in FIGS. 9A to 9C. Therefore, attached substances in the etching process of the silver layer 190 are not attached to the sidewalls of the silicon layer 170 and the silicon oxide layer 180 relating to the pattern 300. That is, the leakage current due to the first cause is not generated.

Further, the silver layer 190 is previously removed, and thus the silver is removed in advance before the diffusion thereof. That is, the leakage current due to the second and third causes is not also generated.

As described above, in the embodiment, the pattern 300 is formed, and the silver layer 190 is not included in the pattern 300 overlapping the second conductive line L2. Thereby, planarization based on CMP is facilitated without increasing the leakage current between the second conductive lines L2.

Next, an example in which the pattern 300 of the embodiment is formed so as to overlap the first conductive line L1 will be described with reference to FIG. 16.

FIG. 16 is a plan view in a state where the second conductive line L2 is formed similarly to FIG. 4, and then the interlayer dielectric film 150c is formed between the second conductive lines L2 and planarization based on CMP is performed. Meanwhile, in the conductive line lead region Rp, the first conductive line material 160 is shown by a broken line.

FIG. 4 is a plan view illustrating the conductive line lead region Rp in the extending direction of the second conductive line L2, whereas FIG. 16 is a plan view illustrating the conductive line lead region Rp in the extending direction of the first conductive line L1. Thus, in FIG. 16, both sides of the drawing are a row direction, and the vertical direction thereof is a column direction.

Similarly to FIG. 4, FIG. 16 also shows an example in which every four first conductive lines L1 have the lead direction thereof changed to both sides of the memory cell region Rm. In addition, similarly to FIG. 4, the pattern 300 is disposed in the conductive line lead region Rp.

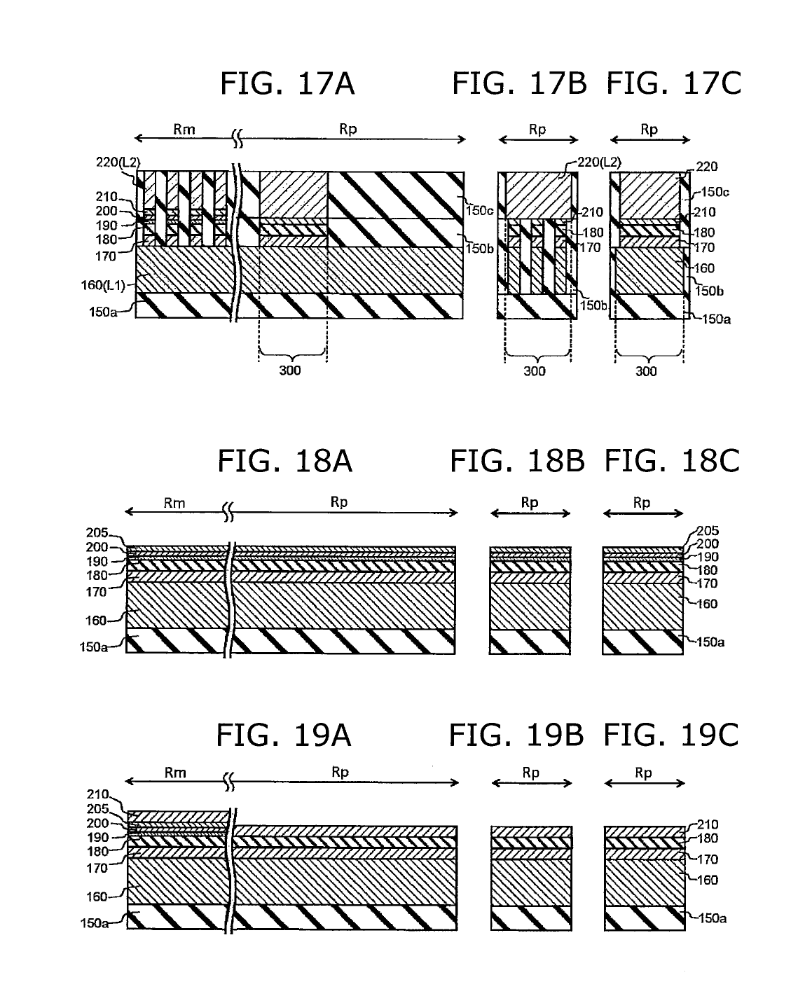

The pattern 300 will be described with reference to the cross-sectional views of FIGS. 17A to 17C. FIG. 17A is a cross-sectional view taken along line A-A′ of FIG. 16. FIG. 17B is a cross-sectional view taken along line B-B′ of FIG. 16. FIG. 17C is a cross-sectional view taken along line C-C′ of FIG. 16.

Specifically, FIG. 17A is a diagram when the row direction cross-section of a region in which the pattern 300 and the first conductive line L1 are formed so as to overlap each other is viewed from a column direction. FIG. 17B is a diagram when the column direction cross-section of the pattern 300 and the first conductive line L1 is viewed from a row direction. FIG. 17C is a diagram when the column direction cross-section of the first conductive line L1 and the pattern 300 formed in a region which does not overlap the second conductive line L2 is viewed from a row direction.

In this case, a memory device can be similarly manufactured by the manufacturing method described in FIGS. 6A to 15C. In addition, the silver layer 190 is not included in a region in which the first conductive line L1 and the pattern 300 overlap each other, and thus planarization based on CMP is facilitated while suppressing a leakage current between the first conductive lines L1.

Subsequently, a variation of the embodiment and the like will be described.

In the above description, an example of the pattern 300 which is formed between the first conductive line L1 and the second conductive line L2 has been given, but there is no limitation thereto. This can be applied between any conductive lines L.

In addition, an example has been described in which the silicon layer 170 is used as the element selection layer 70, the silicon oxide layer 180 is used as the resistance change layer, and the silver layer 190 is used as the metal source layer 80, but there is no limitation thereto.

A compound used in the element selection layer 70 may be metal oxynitride, metal nitride, silicon oxide, silicon nitride, silicon oxynitride, a stacked body thereof, or the like.

A compound used in the resistance change layer 75 is metal oxide, silicon oxide, or a stacked body thereof. An alloy of germanium, antimony and tellurium, or the like may be used.

An element used in the metal source layer 80 may be, for example, gold, palladium, iridium, platinum, tungsten, hafnium, zirconium, titanium, nickel, cobalt, aluminum, chromium, copper, or the like, in addition to silver.

Another variation will be described below. An example has been described in which both the silver layer 190 and the barrier metal layer 200 which are the metal source layer 80 are removed by the etching process of FIGS. 9A to 9C, but there is no limitation thereto. That is, after the formation of the metal source layer 80, these layers may be removed by the etching process. However, the metal source layer 80 is required to be stabilized. Meanwhile, in this case, the formation of the barrier metal layer 200 can be omitted.

Further, another variation will be described below. An example has been described in which the silver layer 190 and the barrier metal layer 200 in regions other than the memory cell region Rm are removed by the etching process of FIGS. 9A to 9C, but there is no limitation thereto. That is, the first conductive line L1 and the pattern 300 in a region overlapping the second conductive line L2 may not include the silver layer 190 and the barrier metal layer 200. That is, the pattern 300 shown in FIG. 5C may include the silver layer 190 and the barrier metal layer 200.

### Second Embodiment

A second embodiment will be described with reference to FIGS. 18A to 20C. In FIGS. 18A to 20C, unless otherwise stated, parts A, parts B, and parts C of the respective figures are schematic cross-sectional views taken along line A-A′, line B-B′, and line C-C′ of FIG. 4, respectively.

As shown in FIGS. 18A to 18C, similarly up to FIGS. 8A to 8C of the first embodiment, the barrier metal layer 200 is formed, and a metal layer 205 is formed thereon. An element used in the metal layer 205 is, for example, tungsten, copper, aluminum, or the like, and the metal layer also functions as an electrode.

Subsequently, as shown in FIGS. 19A to 19C, the metal layer 205, the barrier metal layer 200, and the silver layer 190 in the conductive line lead region Rp are removed, and the CMP stopper electrode layer 210 is formed. The removal thereof is performed by forming a desired mask pattern on the metal layer 205 in the memory cell region Rm, and etching the metal layer 205, the barrier metal layer 200, and the silver layer 190 through RIE or the like using the mask pattern as a mask.

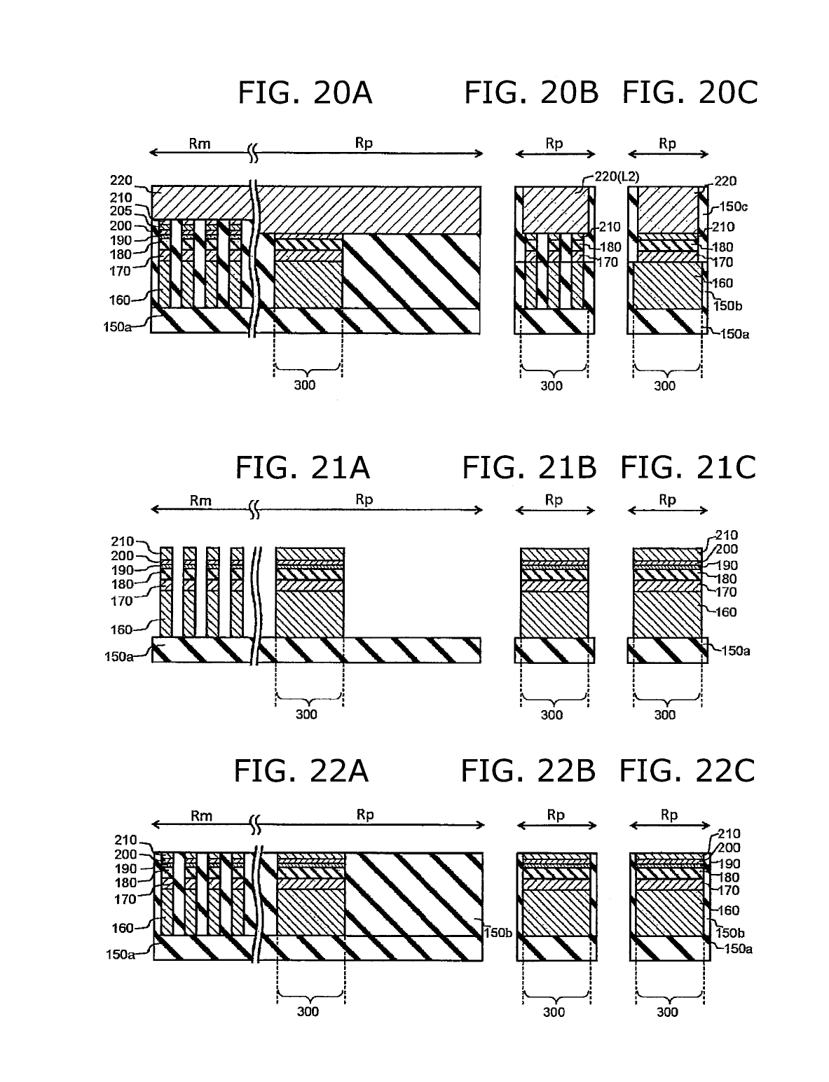

The subsequent processes may be performed similarly to the first embodiment, drawings equivalent to FIGS. 15A to 15C of the first embodiment are shown in FIGS. 20A to 20C.

The difference from the first embodiment is that the metal layer 205 is formed on the barrier metal layer 200 in the memory cell region Rm.

In this manner, the metal layer 205 is provided on the barrier metal layer 200, and thus the role of the barrier metal layer is strengthened, whereby it is possible to prevent the condensation of the silver layer 190, the diffusion of the silver in the silver layer 190, or the change of characteristics due to the oxidation of the silver layer 190.

### Third Embodiment

A third embodiment will be described with reference to FIGS. 21A to 24C. In FIGS. 21A to 24C, unless otherwise stated, parts A, parts B, and parts C of the respective figures are schematic cross-sectional views taken along line A-A′, line B-B′, and line C-C′ of FIG. 4, respectively.

In the embodiment, as shown in FIGS. 21A to 21C, an etching process is first performed.

Similarly up to FIGS. 8A to 8C of the first embodiment, the barrier metal layer 200 is formed, and the CMP stopper electrode layer 210 is formed thereon. Next, a mask material is formed on the CMP stopper electrode layer 210, and a desired mask pattern is formed in a mask material shape. Using this mask pattern as a mask, an etching process as shown in FIGS. 21A to 21C is performed, for example, using an etching process based on RIE.

Subsequently, as shown in FIGS. 22A to 22C, the interlayer dielectric film 150b is formed, and planarization is performed based on CMP.

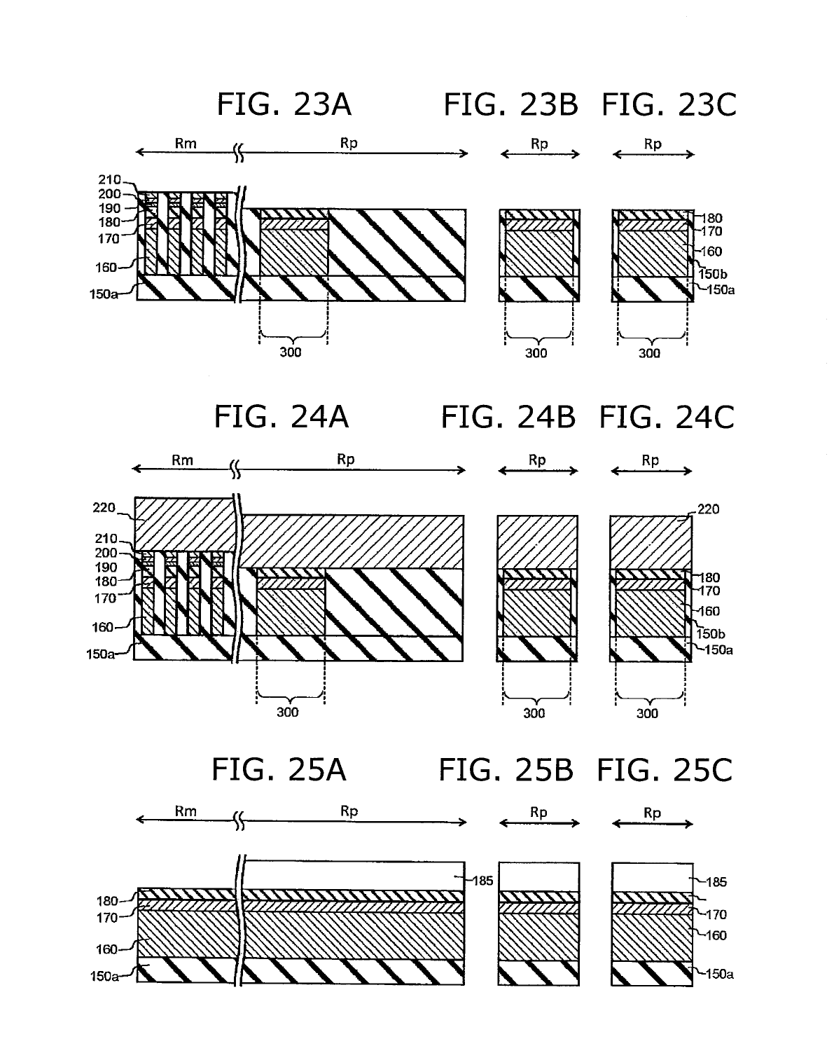

Subsequently, as shown in FIGS. 23A to 23C, the CMP stopper electrode layer 210, the barrier metal layer 200, and the silver layer 190 in the conductive line lead region are removed. A desired mask pattern is formed on the memory cell region Rm by a lithography method or the like, and an etching process is performed based on RIE using this mask pattern as a mask.

Subsequently, as shown in FIGS. 24A to 24C, the second conductive line material 220 is formed. Hereinafter, the same manufacturing method as that in FIGS. 14A to 14C of the first embodiment may be used, and thus the description thereof will not be given.

In the embodiment, a stepped difference between the memory cell region Rm and the conductive line lead region Rp is small at a point in time of the planarization of the interlayer dielectric film 150b shown in FIGS. 22A to 22C based on CMP. Therefore, there is an advantage in that the planarization of the interlayer dielectric film 150b can be performed more easily.

Meanwhile, an example is shown in which the interlayer dielectric film 150b is similarly etched using an etching process in FIGS. 23A to 23C, but the CMP stopper electrode layer 210, the barrier metal layer 200, and the silver layer 190 in FIG. 23A may be able to be removed. That is, conditions in which the interlayer dielectric film 150b and a selection ratio are taken are selected, and the barrier metal layer 200 and the silver layer 190 in the conductive line lead region Rp may be removed.

As seen from the above, after the barrier metal layer 200 and the silver layer 190 are selectively removed, a shape of the pattern 300 has a recessed shape with respect to the periphery. Then, the second conductive line material 220 is embedded in the recessed shape. A film thickness of the interlayer dielectric film 150b is not reduced by selecting such an etching condition. Thus, leakage between layers can be reduced further.

By contrast, the pattern 300 is formed into a projected shape when there is no difference in etching speed among the interlayer dielectric film 150b, the barrier metal layer 200 and the silver layer 190 or etching speed of the interlayer dielectric film 150b faster than the barrier metal layer 200 and the silver layer 190. Then, the second conductive line material 220 is formed along the projected shape of the pattern 300. In this case, since the optimization of an etching condition is easy, there is an advantage in that manufacturing can be easy.

### Fourth Embodiment

A fourth embodiment will be described with reference to FIGS. 25A to 27C. In FIGS. 25A to 27C, unless otherwise stated, parts A, parts B, and parts C of the respective figures are schematic cross-sectional views taken along line A-A′, line B-B′, and line C-C′ of FIG. 4, respectively.

As shown in FIGS. 25A to 25C, similarly up to FIGS. 7A to 7C of the first embodiment, the silicon oxide layer 180 is formed, and a sacrificial layer 185 is formed in the conductive line lead region Rp.

In a method of forming the sacrificial layer 185, for example, the sacrificial layer 185 is formed on the silicon oxide layer 180, and a desired mask pattern is formed thereon. Using this mask pattern as a mask, the sacrificial layer 185 is etched based on RIE.

As the sacrificial layer 185, for example, a resist material, a silicon nitride film, or the like is used.

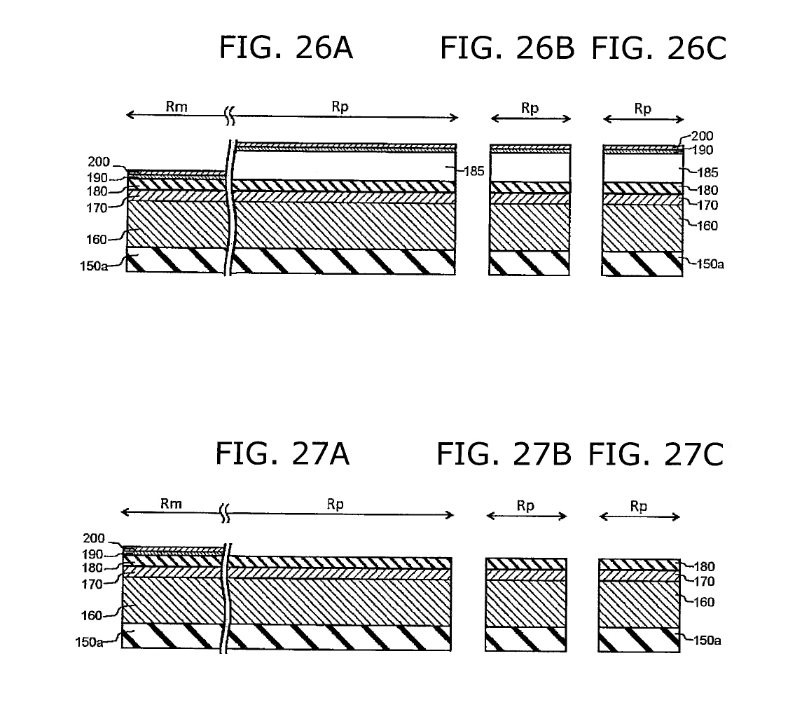

Subsequently, as shown in FIGS. 26A to 26C, the silver layer 190 and the barrier metal layer 200 are formed on the silicon oxide layer 180 and the sacrificial layer 185.

The silver layer 190 and the barrier metal layer 200 are not preferably formed at the sidewall of the sacrificial layer 185 insofar as possible. For example, this can be realized by forming the silver layer 190 and the barrier metal layer 200 using a sputtering method.

Subsequently, as shown in FIGS. 27A to 27C, the sacrificial layer 185 is removed. When the sacrificial layer 185 is removed, the silver layer 190 and the barrier metal layer 200 which are formed on the sacrificial layer 185 are also removed (so-called lifted off).

The subsequent manufacturing methods may be used according to the same methods as those in FIGS. 10A to 10C and the subsequent figures of the first embodiment, and thus the description thereof will not be given.

The sacrificial layer 185 is removed by the following method. For example, when a resist material is used in the sacrificial layer 185, the sacrificial layer can be selectively removed by sulfuric acid hydration or an ashing method. When a silicon nitride film is used in the sacrificial layer 185, the sacrificial layer can be selectively removed by an overheated phosphoric acid.

Meanwhile, when materials other than the silicon oxide layer 180 are used as the resistance change layer 75, a silicon oxide film can also be used in the sacrificial layer 185. When a silicon oxide film is used in the sacrificial layer 185, the sacrificial layer 185 can be selectively removed by using a hydrofluoric acid.

In the embodiment, it is also possible to obtain the same effect as that in the first embodiment.

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

1. A memory device comprising:
a first interconnect extending along a first direction;
a first conductive body apart from the first interconnect in a direction crossing the first direction;
a second interconnect extending in a second direction crossing the first direction;
a memory cell provided between the first interconnect and the second interconnect;
a pattern apart from the memory cell in the second direction,
the memory cell including:
a first resistance change layer which is disposed between the first interconnect and the second interconnect,
a first electrode layer provided below the second interconnect and directly above the first resistance change layer,
a metal source layer provided between the first electrode layer and the first resistance change layer; and
a pattern including:
a second resistance change layer which is disposed between the first conductive body and the second interconnect,
a second electrode which is provided below the second interconnect and directly above the second resistance change layer,
a first distance between a first connect portion of the second interconnection and the first interconnect in a third direction being longer than a second distance between a second connect portion of the second interconnection and the first conductive body in the third direction, the third direction crossing the first direction and the second direction, the first connect portion contacting the first electrode layer, the second connect portion contacting the second electrode layer.

2. The device according to claim 1, further comprising:
an insulating film covering the memory cell and the pattern, and
the pattern being below an upper surface of the insulating film covering the memory cell.

3. (canceled)

4. The device according to claim 1, wherein
the memory cell further includes a first element selection layer provided between the first interconnect and the first resistance change layer,
the pattern further includes a second element selection layer provided between the first conductive body and the second resistance change layer.

5. The device according to claim 1, wherein
the first resistance change layer includes at least one kind of material selected from a group consisting of aluminum oxide, hafnium oxide, zirconium oxide, and silicon oxide,
the second resistance change layer includes at least one kind of material selected from a group consisting of aluminum oxide, hafnium oxide, zirconium oxide, and silicon oxide.

6. The device according to claim 1, wherein
the first resistance change layer includes an alloy of germanium, antimony, and tellurium,
the second resistance change layer includes an alloy of germanium, antimony, and tellurium.

7. The device according to claim 1, wherein the first metal source layer includes a metal configured to be ionized in the first resistance change layer.

8. The device according to claim 1, wherein the first electrode layer and the second electrode layer are stopper films in a chemical mechanical polishing process.

9. The device according to claim 1, wherein the memory cell further includes a first barrier metal layer provided between the first electrode layer and the metal source layer.

10. The device according to claim 9, wherein the pattern further includes a second barrier metal layer provided between the second resistance change layer and the second electrode layer.

11-20. (canceled)

21. The device according to claim 1, wherein
the first conductive body contains a same material as a material contained in the first interconnecting.

22. The device according to claim 1, wherein
the second interconnect provided in a conductive line lead region including the pattern is thicker than the second interconnect provided in the memory region including the memory cell.

23. A memory device comprising:
a first interconnect extending along a first direction;
a first conductive body apart from the first interconnect in a direction crossing the first direction;
a second interconnect extending in a second direction crossing the first direction;
a second conductive body, at least a portion of the second conductive body overlapping the second interconnect in a direction crossing the first direction and a third direction, the second conductive body overlapping the first conductive body in the third direction, the third direction crossing the first direction and the second direction;
a memory cell which is disposed between the first interconnect and the second interconnect;
a pattern which is disposed between the first conductive body and the second conductive body,
the memory cell including:
a first resistance change layer which is disposed between the first interconnect and the second interconnect,
a first electrode layer provided below the second interconnect and directly above the first resistance change layer,
a metal source layer provided between the first electrode layer and the first resistance change layer; and
the pattern including:
a second resistance change layer which is disposed between a first conductive body and the second interconnect,
a second electrode layer which is provided below the second interconnect and directly above the second resistance change layer;
a first distance between a first connect portion of the second interconnect and the first interconnect in the third direction being longer than a second distance between the second conductive body and the first conductive body in the third direction, the first connect portion contacting the first electrode layer.

24. The device according to claim 23, further comprising:
an insulating film covering the memory cell and the pattern, and
the pattern being below an upper surface of the insulating film covering the memory cell.

25. The device according to claim 23, wherein
the memory cell further includes a first element selection layer provided between the first interconnect and the first resistance change layer,
the pattern further includes a second element selection layer provided between the first conductive body and the second resistance change layer.

26. The device according to claim 23, wherein
the first resistance change layer includes at least one kind of material selected from a group consisting of aluminum oxide, hafnium oxide, zirconium oxide, and silicon oxide,
the second resistance change layer includes at least one kind of material selected from a group consisting of aluminum oxide, hafnium oxide, zirconium oxide, and silicon oxide.

27. The device according to claim 23, wherein
the first resistance change layer includes an alloy of germanium, antimony, and tellurium,
the second resistance change layer includes an alloy of germanium, antimony, and tellurium.

28. The device according to claim 23, wherein the memory cell further includes a first barrier metal layer provided between the first electrode layer and the metal source layer.

29. The device according to claim 23, wherein the pattern further includes a second barrier metal layer provided between the second resistance change layer and the second electrode layer.

30. The device according to claim 23, wherein
the first conductive body contains a first material same as a second material contained in the first interconnect,
the second conductive body contains a third material same as a fourth material contained in the second interconnect.

31. The device according to claim 23, wherein
the second interconnect provided in a conductive line lead region including the pattern is thicker than the second interconnect provided in the memory region including the memory cell.
